(19) United States
(12) Patent Application Publication
(10) Pub. No.: US 2013/0276989 A1
(43) Pub. Date: Oct. 24, 2013

(54) PASTE APPLYING APPARATUS AND PASTE APPLYING METHOD, AND DIE BONDER

(71) Applicants: Tatsuyuki OKUBO, Kumagaya (JP); Mitsuo Yoda, Kumagaya (JP); Shigeru Otake, Kumagaya (JP)

(72) Inventors: Tatsuyuki OKUBO, Kumagaya (JP); Mitsuo Yoda, Kumagaya (JP); Shigeru Otake, Kumagaya (JP)

(21) Appl. No.: 13/587,103

(22) Filed: Aug. 16, 2012

(30) Foreign Application Priority Data
Apr. 19, 2012 (JP) 2012-095312

(51) Int. Cl. H01L 21/50

(52) U.S. Cl. 156/578; 118/323; 427/256

(57) ABSTRACT

A paste applying apparatus and method apply a paste within an application area. A drawing pattern is determined in advance, within the application area, for each of the application areas, and the drawing pattern has, at least, a first drawing route and a fifth drawing route for drawing in horizontal direction, a second drawing route and a fourth drawing route for drawing obliquely, and further a third drawing route, in vicinity of a side of the application area in the horizontal direction. A controller portion controls the discharge portion and the moving portion, so that the paste is applied, continuously, from a drawing start-point to a drawing end-point, which are determined in advance, through the first drawing route, the second drawing route, the third drawing route, the fourth drawing route and the fifth drawing route.

This application relates to and claims priority from Japanese Patent Application No. 2012-095312 filed on Apr. 19, 2012, the entire disclosure of which is incorporated herein by reference.

### BACKGROUND OF THE INVENTION

The present invention relates to a die bonder and a semiconductor manufacturing method, and in particular, relates to a paste applying technology to be applied die bonding and part mounting in a semiconductor manufacturing apparatus.

In general, in a manufacturing process of a semiconductor device (or a semiconductor integrated circuit device) is applied a fluid material, such as, a liquid adhesive for use of die bonding (for example, an adhesive of epoxy group), etc., on a substrate to be applied (hereinafter, being called “paste”). In this instance, the paste is charged into a syringe having a applying nozzle (hereinafter, being called “nozzle”) below, in advance, and a compressed gas, such as, an air, etc., is supplied thereto from a dispenser device, for a predetermined time-period, so as to discharge a predetermined amount or volume of the paste from the nozzle of the syringe; thereby applying the paste, such as, the adhesive, on the substrate to be applied therewith (hereinafter, being called “substrate”). When applying, the syringe conducts a drawing operation by scanning on a XY plane, with a single stroke in a 2-dimensional manner, under a condition of bringing the nozzle to be close to the substrate (see the following Patent Document 1).

FIG. 1 is a view for explaining FIG. 4 described in the Patent Document 1. A reference numeral 101 depicts an area for applying an electrode, etc., so as to make bonding with the die on the substrate, 107 the paste, 108, 109 and 110 drawing routes (i.e., the routes of movement of the nozzle when it applies), which is made up with the pastes 107 applied, 111 a start-point of the drawing, and 112 an end-point of the drawing, respectively. In the Patent Document 1, in this manner, the route is made up with three (3) pieces of straight-line drawing routes 108, 109 and 110. As a result of this, through a “Z”-like drawing route, a “Z”-like application (or drawing) pattern is formed on the application area 101 of the substrate. In this case, since the application area 101 is a square, areas of margin portions 115 and 116 are small. For this reason, when bonding a die on the application area 101, which is formed on the substrate, the paste applied thereon can cover the margin portions 115 and 116.

However, the shape of the application area 101, in general, is similar to that of the die, which would be bonded on that application area, and in the case shown in FIG. 1, the die also has a square shape.

### PRIOR ART DOCUMENTS

### Patent Documents

[Patent Document 1] Swiss Patent No. 699664.

### BRIEF SUMMARY OF THE INVENTION

In the Patent Document 1 mentioned above is described the “Z”-like pattern, on a die having an almost square shape, in particular, being small in the size thereof (for example, from 0.8 mm×0.8 mm to 1.8 mm×1.8 mm), achieving an improvement on unevenness of wetting property thereof, compering to a point or dot-like pattern(s), and also achieving an improvement on an application speed comparing to that of a cross-like (i.e., +) application pattern. However, the wetting property in the present specification means the wetting property on a bonding surface between the die and the application area when the die bonds on the application area (when the die is bonded).

Also, in the Patent Document 1, although description is made that this is applicable also to a die having an oblong shape; however, there is no detailed description thereof, in particular.

FIGS. 2A and 2B are views for showing a condition of application of the paste, in case when applying the “Z”-like application pattern disclosed in the Patent Document 1 into the application areas of the oblong shape (for example, 0.5 mm×4 mm). In this FIG. 2, reference numerals 201 and 202 depict the areas for applying electrodes, etc., so as to make boding with the die on the substrate, 217 and 227 the pastes applied, 208, 209 and 210 the drawing routes (i.e., the routes of movement of the nozzle when it applies), which are made up with the pastes 217 applied, 211 the start-point of the drawing, and 212 the end-point of the drawing, respectively.

In FIG. 2A, in this manner, the route is made up with three (3) pieces of straight-line drawing routes 208, 209 and 210. As a result of this, through the “Z”-like drawing route, the “Z”-like application (or drawing) pattern is formed on the application area 201 of the substrate. In this case, since the application area 201 is an oblong, total area of margin portions 215 and 216 are larger than that when being square. For this reason, when bonding the die, the paste applied cannot cover over the margin portions 215 and 216, completely, and there is a possibility that unevenness or un-uniformity of the wetting property is generated. This is clear from the fact that, as is shown in FIG. 2B, the area of the margin portions 215 and 216 comes to be small, when the oblong is shortened in the longitudinal direction thereof than that shown in FIG. 2A.

However, the shapes of the application areas 201 and 221, in general, are similar to that of the die, which would be bonded on that application area, and in the case shown in FIGS. 2A and 2B, the die also has the similar shape of the application area, i.e., the oblong.

Further, even for the die having the square shape, when the size thereof comes to be large, since the margin portions become large for the “Z”-like application pattern, there is generated a necessity of reconsideration of the application pattern and also an improvement of the wetting property thereof.

An object of the present invention is, by taking such problems as mentioned above into the consideration thereof, to provide a paste applying apparatus and a paste applying method for reducing the unevenness or un-uniformity of the wetting property of the application pattern, as well as, a die bonder.

For accomplishing the object mentioned above, according to the present invention, there is provided a paste applying apparatus, for applying a paste within an application area, with discharging the paste from a nozzle, comprising: a discharge portion, which is configured to discharge the paste from the nozzle of a syringe; a moving portion, which is configured to move said nozzle in relative to a predetermined application area of a substrate; and a controller portion, wherein a drawing pattern is determined in advance, within said application area, for each of said application areas, and said drawing pattern has, at least, a first drawing route and a fifth drawing route for drawing in horizontal direction, a second drawing route and a fourth drawing route for drawing obliquely, and further a third drawing route, in vicinity of a side of said application area in the horizontal direction, and said controller portion controls said discharge portion and said moving portion, so that said paste is applied, continuously, from a drawing start-point to a drawing end-point, which are determined in advance, through said first drawing route, said second drawing route, said third drawing route, said fourth drawing route and said fifth drawing route, as a first feature according to the present invention.

Also, for accomplishing the object mentioned above, according to the present invention, there is provided a paste applying for an apparatus, applying a paste within an application area, with discharging the paste from a nozzle, comprising: a discharge portion, which is configured to discharge the paste from the nozzle of a syringe; a moving portion, which is configured to move said nozzle in relative to a predetermined application area of a substrate; and a controller portion, in said method; a drawing pattern is determined in advance, within said application area, for each of said application areas, and said drawing pattern has, at least, a first drawing route and a fifth drawing route for drawing in horizontal direction, a second drawing route and a fourth drawing route for drawing obliquely, and further a third drawing route, in vicinity of a side of said application area in the horizontal direction; and said controller portion controls said discharge portion and said moving portion, so that said paste is applied, continuously, from a drawing start-point to a drawing end-point, which are determined in advance, through said first drawing route, said second drawing route, said third drawing route, said fourth drawing route and said fifth drawing route, as a second feature according to the present invention.

In the paste applying apparatus as the first feature according to the present invention mentioned above, or the paste applying method as the second feature according to the present invention mentioned above, said application area is an oblong, having a long side in vertical direction with respect to other side in said horizontal direction, as a third feature according to the present invention.

In the paste applying apparatus as the first feature according to the present invention mentioned above, or the paste applying method as the second feature according to the present invention mentioned above, said third drawing route lies in a direction perpendicular to the side of the application area in said horizontal direction, as a fourth feature according to the present invention.

Further, for accomplishing the object mentioned above, according to the present invention, there is further provided a die bonder comprising: a wafer supply portion, which is configured to supply a die; a work supply/transfer portion, which is configured to transfer a substrate; a pre-form portion, having a syringe for applying a paste within an application area by discharging an adhesive onto said substrate and a driving mechanism, which is configured to move said syringe; a bonding head portion, which is configured to bond said die on said application area of said substrate, on which said paste is applied; and a controller portion, which is configured to control said wafer supply portion, said work supply/transfer portion, said pre-form portion and said bonding head portion, wherein a drawing pattern is determined in advance, within said application area, for each of said application areas, and said drawing pattern has, at least, a first drawing route and a fifth drawing route for drawing in horizontal direction, a second drawing route and a fourth drawing route for drawing obliquely, and further a third drawing route, in vicinity of a side of said application area in the horizontal direction, said pre-form portion comprises a discharge portion, which is configured to discharge the paste from said nozzle of said syringe, a moving portion, which is configured to move said nozzle in relative to a predetermined application area of a substrate, and a controller portion, wherein said controller portion controls said discharge portion and said moving portion, so that said paste is applied, continuously, from a drawing start-point to a drawing end-point, which are determined in advance, through said first drawing route, said second drawing route, said third drawing route, said fourth drawing route and said fifth drawing route, as a fifth feature according to the present invention.

According to the present invention mentioned above, it is possible to provide the paste applying apparatus and the paste applying method for reducing the unevenness or un-uniformity of the wetting property of the application pattern, as well as, the die bonder.

### BRIEF DESCRIPTION OF THE SEVERAL VIEWS OF THE DRAWING

Those and other objects, features and advantages of the present invention will become more readily apparent from the following detailed description when taken in conjunction with the accompanying drawings wherein:

FIG. 1 is a view for explaining an example of a paste application pattern according to the conventional art;

FIGS. 2A and 2B are views for showing an example of a paste application pattern according to the conventional art;

FIG. 3 is a perspective view for showing an example of a paste applying apparatus to be applied, according to the present invention;

FIG. 4 is a block diagram for showing an embodiment of a main control portion and a control system thereof within the paste applying apparatus to be applied, according to the present invention;

FIG. 5 is a flowchart for showing an example of an entire operation of the paste applying apparatus 100 to be applied, according to the present invention;

FIGS. 6A, 6B and 6C are views for showing examples of a drawing pattern, to be applied in the paste applying apparatus, a paste applying method and a die bonder, according to the present invention;

FIG. 7 is a plane view for showing the structure of the die bonder, as an embodiment according to the present invention;

FIG. 8 is a block diagram for explaining a control in connection with a paste applying operation in the die bonder, according to the present invention;

FIGS. 9A and 9B are views for explaining an example of the drawing pattern, to be applied in the paste applying apparatus, the paste applying method and the die bonder, according to the present invention;

FIG. 10 is a view for explaining an example of the drawing pattern, to be applied in the paste applying apparatus, the paste applying method and the die bonder, according to the present invention; and

FIGS. 11A to 11C are views for explaining an example of the drawing pattern, to be applied in the paste applying apparatus, the paste applying method and the die bonder, according to the present invention.

### DETAILED DESCRIPTION OF THE PREFERRED EMBODIMENTS

Hereinafter, embodiments according to the present invention will be fully explained by referring to the attached drawings.

However, the explanation, which will be given below, is only for the purpose of explaining an embodiment(s) according to the present invention, but will not limit the scope of the present invention. Accordingly, for the person skilled in the art, it is possible to apply an embodiment, replacing each or all element(s) of those with an equivalent(s) thereof, and also those fall into the scope of the present invention.

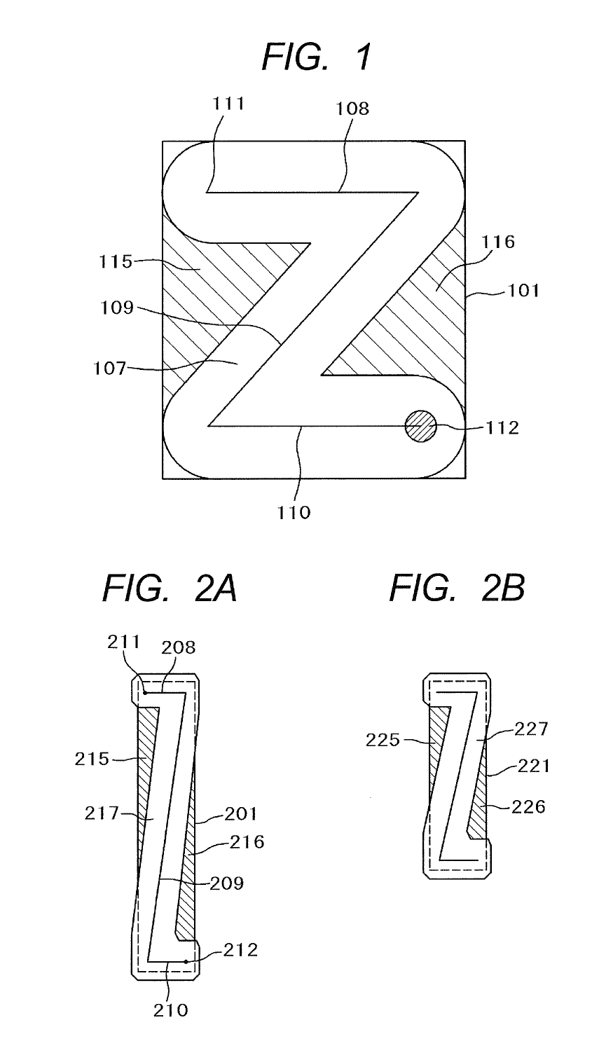

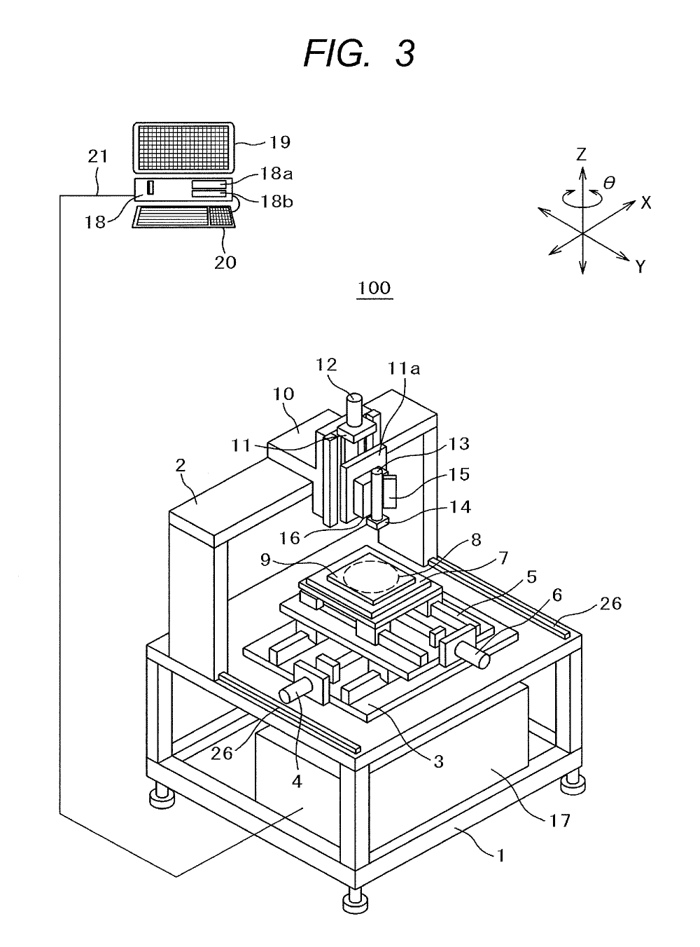

Also, in this specification, same reference numerals will be given to the constituent elements, each having a common function, in the explanation of each drawing, including those of FIGS. 1 and 2, which were already explained, and the explanation thereof will be omitted.

### Example 1

Hereinafter, explanation will be given on a first embodiment of the present invention, by referring to FIG. 3. This FIG. 3 is a perspective view for showing an embodiment of a paste applying apparatus according to the present invention. Thus, this FIG. 3 is the perspective view for showing an embodiment of the paste applying apparatus of “1” in the number of a syringe thereof.

In the paste applying apparatus 100 shown in FIG. 3, on a platform 1 is provided an X-axis moving table 3, and on this X-axis moving table 3 is provided a Y-axis moving table 5, crossing therewith orthogonally. This Y-axis moving table 5 moves into an X-axis direction on the X-axis moving table 3, through driving of an X-axis servomotor 4, which is provided on the X-axis moving table 3. On the Y-axis moving table 5 is provided a substrate supporting mechanism 7. This substrate supporting mechanism 7 moves into a Y-axis direction on the Y-axis moving table 5, through driving of a Y-axis servo motor 6, which is attached on the Y-axis moving table 5. Also, a θ-axis moving table 8 is attached on the substrate supporting mechanism 7, and the substrate supporting mechanism 7 is rotationally driven into a θ-axis direction (i.e., a rotating direction around a Z-axis), through rotationally driving of the θ-axis moving table 8 by means of a θ-axis servo motor not shown in the figure. A substrate 9 is attached on the substrate supporting mechanism 7, and then it moves into the X- or Y-axis direction, or rotates into the θ-axis direction, through the driving of the servo motor of each moving table 3, 5 or 8; thereby being positioned at a predetermined position.

However, in the embodiment shown in FIG. 3, the positioning is made while moving the substrate 9 into a surface direction thereof, and is conducted also applying of a fluid material thereon. However, it is needless to say that controls can be made on the positioning and the application of paste, in the similar manner, by moving a nozzle. Further, an entire mechanism for driving those moving tables 3, 5 and 8, or a mechanism for moving a syringe 13 and a nozzle 13a on the surface direction of the substrate 9, will be called, collectively, a table driving mechanism.

For example, a Z-axis table supporting platform 2 may move into the Y-axis direction on the guide rail 26, a guide rail for X-axis direction moving (not shown in the figure) may be provided on the Z-axis table supporting platform 2, and a Z-axis moving table supporting bracket 10 may be provided to move along the guide rail; so that it may move into the X-axis direction. However, the driving portion is already well-known, and therefore an illustration thereof will be omitted.

On the platform 1 is also provided the Z-axis table supporting platform 2, and on this Z-axis table supporting platform 2 is provided a Z-axis moving table 11, via the Z-axis moving table supporting bracket 10. On the Z-axis moving table 11 is attached a support base 11a to be movable in the Z-axis direction, and through driving of a Z-axis servo motor 12, which is attached on the Z-axis moving table 11, the support base 11a moves into the Z-axis direction (i.e., the vertical direction) (this driving system will be called a nozzle driving mechanism, hereinafter). On this support base 11a are attached the syringe 13 having a nozzle supporting tool 14 at the lower end thereof, a video recognition camera 15 having a lens tube including a light source therein, with which a lighting can be made, and a telemeter 16, etc. Although not shown in the figure, at a tip of this nozzle supporting tool 14 is provided the nozzle.

However, the syringe 13 is attached on a movable portion of a liner guide not shown in the figure, in a detachable manner. Also, the video recognition camera 15 is provided so as to face to the substrate 9, for positioning and recognizing the shape or configuration of the paste pattern.

Also, in a lower portion of the platform 1 is provided a main controller portion 17, and this main controller portion 17 is connected with a sub-controller portion 18, being provided separately therefrom, through wiring 21. The sub-controller portion 18 has an external memory device using a memorizing medium, such as, a hard disc 18a or a DVD 18b, etc, a monitor 19 and a keyboard 20.

The main controller portion 17 controls the servomotor 4, 6 or 12 of each table 3, 5 or 11, or the servomotor of the θ-axis moving table 8. Data for various kinds of processing in the main controller portion 17 are inputted from the keyboard 20. Also, the video captured by the video recognition camera 15 and/or a processing condition in the main controller portion 17 is/are displayed on the monitor 19. Also, the data inputted from the keyboard 20 and so on are memorized and stored on the memory medium, such as, the hard disc 18a or the DVD 18b, i.e., the external memory device.

Such paste applying apparatus 100 as was mentioned above is installed into a die bonder, which will be mentioned later, for example.

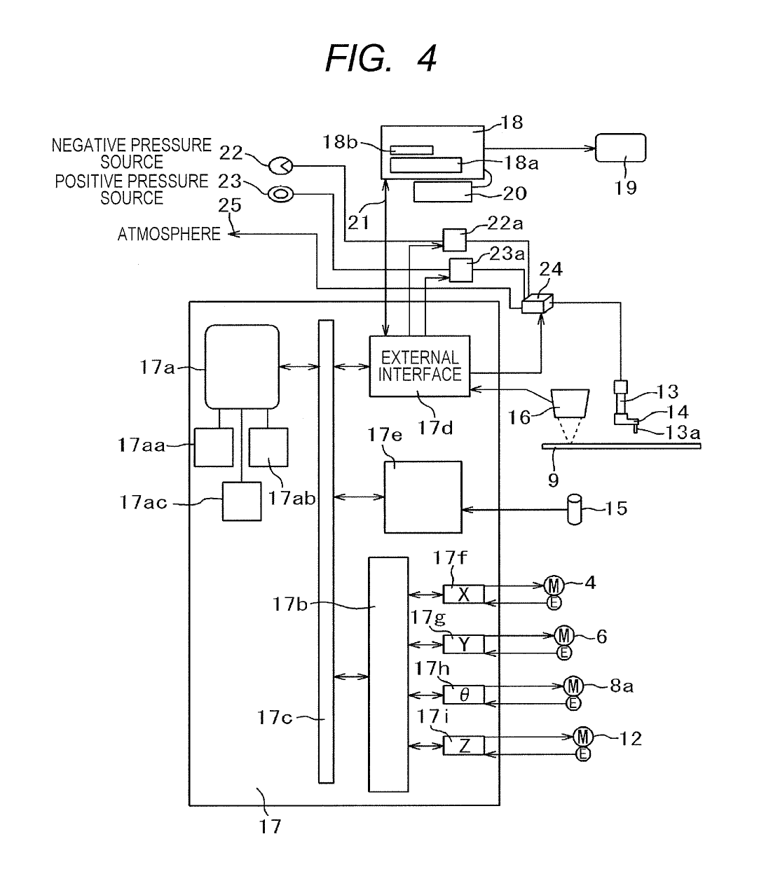

Next, explanation will be made on a method for controlling the paste applying apparatus 100 shown in FIG. 3, by referring to FIG. 4. This FIG. 4 is a flowchart for showing a detailed example the main controller portion 17 and the controlling system thereof shown in FIG. 3.

In FIG. 4, the main controller portion 17 includes a CPU (Central Processing Unit) 17a, a motor controller 17b, motor drivers 17f to 17i, a video processor device 17e, and an external interface 17d built therein. Herein, the video processor device 17e processes a video signal, which can be obtained by the video recognition camera 15. Also, the external interface 17d conducts transmission of signals between the sub-controller portion, controls of regulators 22a and 23a, a valve unit 24, and measurement/input of the telemeter 16.

The CPU 17a, the motor controller 17b, the external interface 17d and the video processor device 17e are connected with one other through a data communication bus 17c.

Also, the CPU 17a comprises a ROM 17aa, a RAM 17ab and an input/output portion 17ac. The ROM 17aa stores therein a processing program for conducting the calculation and/or the application drawing within a main calculator portion. Also, the RAM 17ab stores therein a result of the processing in the main calculator portion and/or input data from the external interface 17d and the motor controller 17b. Also, the input/output portion 17ac transmits data between the external interface 17d and/or the motor controller 17b, upon an operation made by a user.

Also, within the ROM 17aa is stored program data, such as, an application area position in each substrate and paste application information, etc., for each of the substrates to be applied with the paste thereon. However, the paste application information, being the data about the application operation, includes, for example, a route of paste application drawing, a starting point of drawing, an ending point of drawing, a transit point, a moving velocity of the nozzle, a kind of the syringe 13, a discharge pressure, a kind of the nozzle 13a, height of discharging, etc.

Among those data, the data of a target substrate is read out into the RAM 17ab, to be used in the paste application.

And, the CPU 17a generally controls the operations in relation to the paste applying apparatus 100, in accordance with an operation program, which is stored in the ROM 17aa.

The θ-axis servomotor 8a rotationally drives the servomotor 4, 6 or 12 for driving the each table 3, 5 or 11 mentioned above, and the θ-axis moving table 8 (see FIG. 3). This θ-axis servo motor 8a has a built-up encoder therein, for detecting an amount of rotation, and feeds a detection result thereof back to the motor drivers 17f, 17g, 17i and 17h corresponding thereto; thereby conducting position controls of the substrate 9 and the nozzle 13a.

The servomotors 4, 6 8a and 12 rotate, regularly/reversely, upon basis of data, which is inputted from the keyboard 20 and stored in the RAM built within the CPU 17a. With this, the substrate 9 held by the substrate supporting mechanism 7 moves predetermined distances in the X- and Y-directions, arbitrarily, with respect to the nozzle 13a, which is held through the Z-axis moving table 11. During the time of movement thereof, with a slight pressure being applied onto the syringe 13, continuously, the paste, e.g., the fluid material, is discharged from a paste discharge opening, which is provided at the tip of the nozzle 13a, and thereby a desired drawing pattern is applied/drawn within a predetermined application area of the substrate 9. This drawing pattern is determined, in advance, for each of the application areas on the substrate 9, and is stored in the memory device, such as, the ROM, etc.

A discharge pressure controlling mechanism for controlling the application of the fluid material, such as, the paste, etc., is made up with regulators 22a and 23a, and valve unit 24. The regulator 22a adjusts the pressure of a vacuumed air, which is supplied from a negative pressure source 22. Also, the regulator 23a adjusts the pressure of a compressed air, which is supplied from a positive pressure source 23. Also, the valve unit 24 controls exchange between conduits for the airs adjusted by those regulators 22a and 23a, and a conduit opened to an atmosphere 25, respectively.

With this discharge pressure controlling mechanism, a desired pressure is applied from the valve unit 24 onto the fluid material, such as, the paste, etc., within the syringe 13, and the discharge pressure is controlled.

Also, during the horizontal movement into the X- and Y-directions of the substrate 9 held by the substrate supporting mechanism 7, the telemeter 16 measures a gap or distance between the nozzle 13a and the substrate 9 (hereinafter, being called a “height” of the nozzle 13a). Upon basis of a result of this measurement is driven the Z-axis servo motor 12, so that the height of the nozzle 13a is maintained to be almost constant. Also, upon basis of the result of this measurement is driven the Z-axis servo motor 12, so that the nozzle 13a is controlled on the movement in the Z direction.

Although the paste applying apparatus 100 adopts the servo motor, as the motor for driving each axis, however in the place thereof may be also applied a DC motor, a linear motor, a vibration motor, a stepping motor, a universal motor, etc.

FIG. 5 is a flowchart for showing an embodiment of the entire operation of the paste applying apparatus 100 to be applied in the present invention. Hereinafter, explanation will be given on the operation of this embodiment, by referring to FIG. 3 and also FIG. 4, as well.

In FIG. 3, first of all, when a power source is turned “ON”, in a step S100 is executed an initial setting of the paste applying apparatus.

After step of this initial setting, in a step S200, through driving the servo motors 4, 6, 8a and 12, the substrate supporting mechanism 7 is moved into the X-, Y- and θ directions, and positioned at a predetermined reference position. Also, at the same time of this, the nozzle 13a is set at a predetermined original or starting point, so that the paste discharge opening is located at a position where it should starts the paste application (i.e., a starting point of application of the fluid material). Further, setting is made on pattern data of the fluid material, substrate position data and data of an ending position of discharge of the fluid material, etc. However, as was mentioned previously, an input of each of those data is conducted through the keyboard 20, and the data inputted is store in the RAM built within the CPU 17a.

Next, in a sep S300, the substrate 9 is mounted on the substrate supporting mechanism 7, to be held thereon, and following to this is conducted a process for provisionally positioning the substrate.

In this process for provisionally positioning the substrate, a positioning mark of the substrate 9 mounted on the substrate supporting mechanism 7 is picked up or photographed by the video recognition camera 15, so as to obtain a position of the gravity center for use in the positioning from that video pick, and also an inclination of the substrate 9 in the θ-axis direction is detected, and thereby driving the servo motor 8a depending on those, as well as, correcting the inclination in this θ-axis direction.

However, in case where a remaining amount or volume (e.g., an amount of content) is small, of the fluid material, such as, the paste, etc., within the syringe 13, the syringe 13 is exchanged together with the nozzle 13a thereof, in advance, for the purpose of avoiding a break of the fluid material on the way of a next paste application work. In case where the syringe 13 is exchanged together with the nozzle 13a, there is a possibility that the position thereof is shifted on a surface of the X- and Y-axes. For avoiding this shift of position, a cross (+) mark is drawn with using a new nozzle 13a, which is exchanged, within a region or an area where no pattern is formed on the substrate 9, and this cross mark is picked up or photographed by the video recognition camera 15, so as to obtain a position of the gravity center at a crossing point of the cross mark through video processing. Then, calculation is made on a distance between the position of the gravity center and the position of the gravity center of the positioning mark on the substrate 9, and a result of that calculation is stored in the RAM built within the CPU 17a, as a shifting amount of the position (dx,dy) of the discharge opening for the fluid material of the nozzle 13a. With this is completed the process for provisionally positioning the substrate (a step S400).

The shifting amount of the position (dx,dy) of the nozzle 13a is to be used for correcting the position shift of the nozzle 13a, when it operates the application/drawing of the pattern, which will be conducted later.

Next, in the step S400 is conducted a process for drawing a pattern of the fluid material.

In this pattern drawing process, for positioning the discharge opening for the fluid material of the nozzle 13a at an application starting position, the substrate 9 is moved, and then conducted comparison and an adjustment movement of the position of the nozzle 13a. For this reason, first of all, it is determined if the shifting amount of the position (dx,dy) of the nozzle 13a, which was obtained in the previous process for provisionally positioning the substrate (step S400) and stored in the RAM 17ab of the CPU 17, lies within a permissible range (ΔX, ΔY) or not, of the shifting amount of the position of the nozzle 13a determined in advance.

If the shifting amount of the position lies within this permissible range (ΔX≧dx and ΔY≧dy), the nozzle is kept as it is, but if this shifting amount of the position is out of the permissible range (ΔX<dx and ΔY<dy), upon basis of this shifting amount of the position (dx,dy), the substrate 9 is moved, to dissolve the shift between the discharge opening for the fluid material of the nozzle 13a and the desired position of the substrate 9, and thereby positioning the nozzle 13a at the desired position thereof.

Next, the Z-axis servo motor 12 is operated, so as to set the height of the nozzle 13a to a pattern drawing height. Upon basis of the data of distance of an initial movement of the nozzle, the nozzle 13a is descended by the distance of initial movement. Following thereto, through measurement of the height of the surface of the substrate 9 by the telemeter 16, it is confirmed if the height of the nozzle 13a is set at the height or not, for drawing the pattern of fluid material. If it is not set at the height for drawing, the nozzle 13a is descended by a very small distance, and hereinafter, the measurement of the height of surface of the substrate 9 and the very small distance descent of the nozzle 13a are repetitively conducted, alternately; thereby determining the height of the nozzle 13a at the height same to the height for applying and drawing the pattern. Also, in case where the syringe 13 is not exchanged, since there is no data of shifting amount of the position (dx,dy), the determination of height of the nozzle 13a mentioned above is conducted, directly, when it enters into the process for drawing the pattern.

When the process mentioned above is ended, next, upon basis of the pattern data of the fluid material, which is stored in the RAM 17ab of the CPU 17a, the servo motors 4 and 6 are driven. With this, the substrate 9 is moved in the X and Y directions, depending on this pattern data, under the condition that the paste discharge opening of the nozzle 13a faces to the substrate 9. And, accompanying with this, the predetermined discharge pressure is applied into the syringe 13 from the positive pressure source 23 via the regulator 23a and the valve unit 24, so that the paste is started to be discharged from the paste discharge opening of the nozzle 13a of the syringe 13. With this, the application/drawing operation onto the substrate 9 is started.

And, with this, as was explained previously, the CPU 17a inputs data of an actual measurement of the height of the nozzle 13a from the telemeter 16, so as to measure swell or winding on the surface of the substrate 9 from this actual measurement data, and operates the nozzle driving mechanism (i.e., the Z-axis servo motor 12) depending on this measured value. With this, the height of the nozzle 13a is maintained to be nearly constant at the setting value.

In a step S500, the substrate 9, on which the application/drawing is completed, is discharged.

In a step S600, determination is made of the application work is completed or not, for all of the substrates. If no, then the process turns back to the step S200. Or, if the application work is completed for all of the substrates, the power source of the apparatus is turned “OFF”.

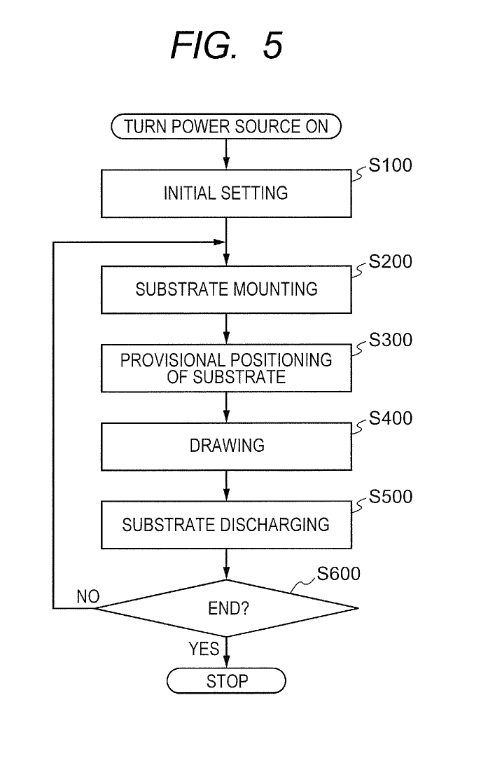

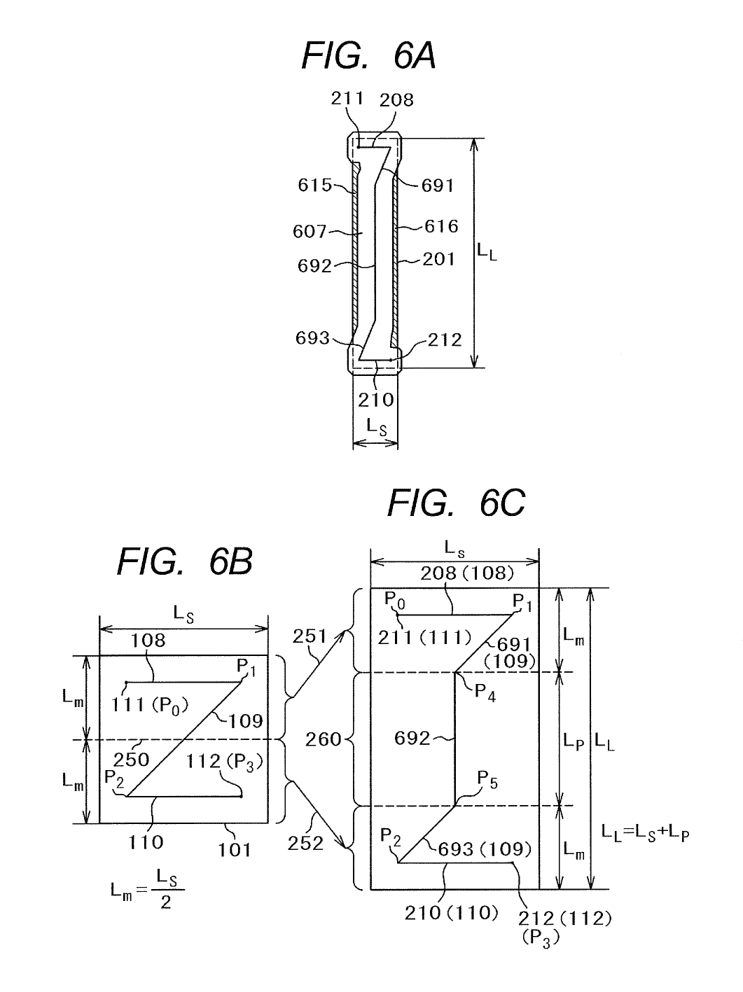

Next, explanation will be made on the drawing pattern to be drawn/applied by the paste applying apparatus mentioned above, by referring to FIGS. 3 to 6C. FIGS. 6A to 6C are drawings for explaining the paste applying apparatus and the paste applying method, and further an example of the drawing pattern to be applied in a die bonder. FIG. 6A is a drawing for explaining an example of the paste drawing pattern according to the present invention. FIG. 6B is a drawing of picking up FIG. 1, again. Also, FIG. 6C is a drawing for explain a drawing route of the drawing pattern shown in FIG. 6A, to be a drawing route added to the drawing pattern shown in FIG. 1. Thus, although differing therefrom in the size of display on the drawing (i.e., emphasis is made on the length in the horizontal direction), the application area and the drawing pattern shown in FIG. 6C are completely same to those shown in FIG. 6A.

As is shown in FIG. 6A, the paste 607 is drawn/applied by means of the syringe 13, starting from the drawing start-point 211, and then the drawing routes 208, 691, 692, 693 and 210, in the order thereof, and when reaching to the drawing end-point 212, it is formed as the drawing pattern.

As a result of this, the nozzle 13a passes through the straight drawing route 692 nearly in parallel with the longitudinal direction of the application area 201, and then the paste is drawn/applied to be long, linearly; therefore, a margin portion (i.e., an area or region where no paste is applied) can be made small comparing to the application area 201. As a result of this, it is possible to reduce the unevenness or un-uniformity of the wetting, even if a die is bonded thereon.

In FIG. 6B, the drawing patter within the application area 101 is made up with a drawing route 108, staring from the drawing start-point 111 (a point P₀) to a first point P₁, a drawing route 109, staring from the first point P₁ to a second point P₂, and a drawing route 110, staring from the second point P₂ to the drawing end-point 212 (a point P₃). However, length of the side of the application area 101 in the horizontal direction and length thereof in the vertical direction are same, i.e., a square, and the length of those sides is “Ls”, being same to the length of a short side in the horizontal direction of that shown in FIG. 6A.

The application area 101 and the drawing pattern shown in FIG. 6B are divided by a broken line 250, equally, into an upper and a lower. Divided length “Lm” in the vertical direction is a half (½) of the length “Ls”. As a result of this, an upper portion shown in FIG. 6B, as is shown by an arrow 251, can be divided and disposed in an upper portion shown in FIG. 6C, and a lower portion shown in FIG. 6B, as is shown by an arrow 252, can be divided and disposed in a lower portion shown in FIG. 6C.

And, by adding the application area 260 and the drawing pattern 692 between the upper portion and the lower portion, it is possible to build up such drawing route(s) as shown in FIG. 6A.

The application areas 201 shown in FIG. 6C has the structure of sandwiching the application area 260 between the application areas 101 shown in FIG. 6B. And, the drawing route 109 is divided into two pieces of drawing routes 691 and 693 by the broken line 250. Thus, it is divided into two (2) pieces; i.e., the drawing route 691 from the point P₁ to P₄, and the drawing route 693 from the point P₅ to P₂. And, the point P₄ and the point P₅ are connected therebetween, by the drawing route 692 being in parallel with the longitudinal side.

And, as was mentioned in FIG. 6A, the paste is applied/drawn from the drawing start-point 211 (111) to the drawing end-point 212 (112), along the drawing route 208 (108), the drawing route 691, the drawing route 692, the drawing route 693, and the drawing route 210 (110), continuously.

Namely, the drawing pattern of the example of the present invention shown in FIGS. 6A-6C has, at least, a first drawing route and a fifth drawing route for drawing in the horizontal direction, and a second drawing route, a fourth drawing route and a third drawing route for drawing in an oblique direction, and it is for applying the paste mentioned above, continuously, from the drawing start-point up to the drawing start-point, which are predetermined, i.e., along the first drawing route, the second drawing route, the third drawing route, the fourth drawing route and the fifth drawing route, while controlling the discharge means and the moving means under the control of the controller portion.

However, any one of the drawing routes shown in FIGS. 6A and 6B is a straight line.

Also, in the embodiment mentioned above, the nozzle 13a may be stopped for a predetermined time-period at a point (i.e., a position) where it moves the drawing route, i.e., from a previous one to a new one. Also, the discharge condition (for example, a drawing speed and a discharge pressure, etc.) may be changed, respectively, on each of the drawing routes. As a result of this, it is possible to achieve an optimal paste application.

### Embodiment 2

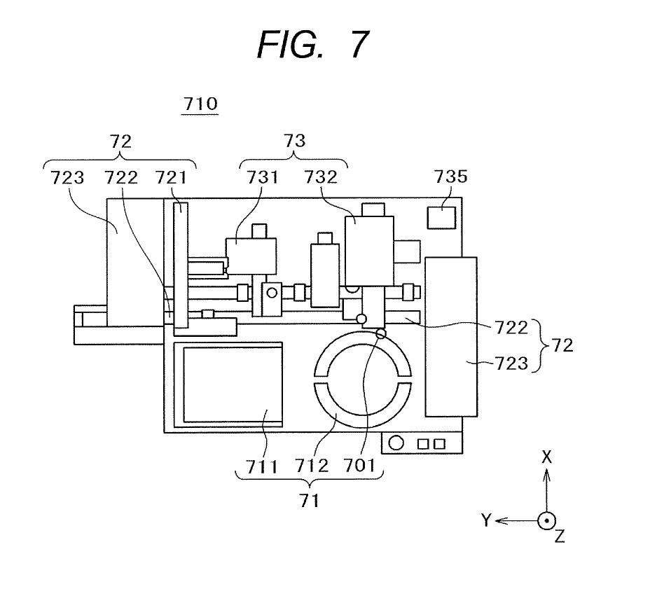

Next, explanation will be made on the die bonder applying therein the paste applying apparatus and the paste applying method according to the present invention, by referring to FIG. 7. In this FIG. 7 are applied the paste applying apparatus and the paste applying method, which are explained in the first embodiment of the present invention.

In the die bonder, after applying the paste onto the application area of the substrate 9, the substrate 9 is transferred to a die bonding position on a transmission path, and is positioned thereat. And, on the paste applied within the application area is bonded a die, which is picked up from a wafer by means of a picking-up tool of a bonding head.

FIG. 7 is a plane view for showing the structure of the die bonder according to the present invention, i.e., an outlook view for showing the die bonder from the above. A wafer supply portion 71 is made up with a wafer cassette lifter 711 and a pickup devise 712. Also, a work supply/transfer portion 72 is made up with a stuck loader 721, a frame feeder 722 and an un-loader 723. Also, a die bonding portion 73 is made up with a pre-form portion 731 and a bonding head portion 732.

In this manner, roughly speaking, the die bonder 710 has the wafer supply portion 71, the work supply/transfer portion 72, the die bonding portion 73, and a controller portion 735.

Though not illustrated in FIG. 7, however the die bonder 710 has, further, a driving mechanism, a recognition processor portion and a monitor, wherein the controller portion 735 communicates with other equipment through an interface. Also, the controller portion 735 is a CPU, for example, and has the structure of being connected with a RAM and a ROM (Read Only Memory), as a memory thereof (see FIG. 8, which will be mentioned later).

The wafer supply portion 71 has at least the wafer cassette lifter 711, the pickup devise 712, and also a die recognition camera 701. The wafer cassette lifter 711 has a wafer cassette (not shown in the figure), into which wafer rings are packed, and the wafer rings are supplied to the pickup devise 712, one by one.

Also, the controller portion 735 controls the operation relating to picking-up of the die and die mounting of the die bonder, generally.

Also, in the work supply/transfer portion 72, a work (e.g., a lead frame, a substrate, etc.), which is supplied to the frame feeder 722 by the stuck loader 721, is transferred to the un-loader 723 through the processing positions provided at two (2) positions on the frame feeder 722.

In the die bonding portion 73, the pre-form portion 731 applies a die adhesive on the work, which is transferred by the frame feeder 722. The bonding head portion 732 goes up after picking up the die from the pickup devise 712, and moves the die in the horizontal direction up to a bonding point on the frame feeder 722. And, the bonding head portion 732 descents the die to make the die bonding on the work, on which the die adhesive is applied. However, the pre-form portion 731 is a main portion of the above-mentioned paste applying apparatus according to the present invention.

The die recognition camera 701, before picking up the die from the wafer, relatively moves to the position, upon basis of mapping data (in actual, the wafer ring holding the wafers moves into the X- and Y-directions), and picks up an image or photographs of an object of that picking-up operation, to be outputted to the controller portion 735. And, the controller portion 735 detects the correct position of that die, through pattern recognition, and compensates the positions of an up-thrust (or pushing up) unit (not shown in the figure) and the pickup devise 712 (in actual, in many cases, the wafer ring holding the wafers moves into the X- and Y-directions), so that the die is picked up by the up-thrust unit and the picking-up tool. After picking up the die, the picking-up tool absorbs or attaches the die thereon, and moves to the bonding point on the frame feeder 722; thereby conducting the die bonding.

For the purpose of bonding the die onto the bonding point, correctly, when the die is picked up from the wafer, detection is made on the position shift of the die attached on the picking-up tool, which is generated from that, so as to compensate the position thereof. Thus, the die after being picked up is photographed by a camera (e.g., an under vision camera (not shown in the figure)), from a reverse surface thereof, so as to detect a center position on the reverse surface of the die, through video recognition of the video photographed, and an amount of shifting of the position is calculated to compensate, and thereby increasing up an accuracy of the die bonding on the substrate.

Next, explanation will be made on the control of paste application operation in the die bonder, by referring to FIG. 8. This FIG. 8 is a block diagram for explaining the control relating to the paste application in an embodiment of the die bonder according to the present invention. A CPU substrate 801 controls a motor control substrate 810, an I/O substrate 820, an operation panel 830, a hard disc 840 and a communication substrate 850, through an interface not shown in the figure.

Also, the motor control substrate 810 controls a pre-form X-axis motor 811. Also, the motor control substrate 810 controls a pre-form Y-axis motor 812. And, the motor control substrate 810 controls a pre-form Z-axis motor 813.

Further, receiving a control signal transmitted when the CPU substrate 801 detects an abnormality of the apparatus, the I/O substrate 820 controls a buzzer rumbling portion 821 and an alarming light display device 831, and thereby starting the buzzer rumbling and the alarming light display operation.

Further, also the hard disc 840, storing a control program of the die bonder 710 therein, controls a control program portion 841 and a data storage/readout portion 842 for storing and reading out the data, appropriately, depending on the control of the CPU substrate 801.

Also, further, the communication substrate 850 controls a dispenser portion 851, upon basis of the control signal, which is transmitted from the CPU substrate 801, so as to discharge the paste from the syringe 13. This paste discharging operation by means of the dispenser portion forms the above-mentioned drawing pattern shown in FIG. 6, on the application area 101 on the substrate 9, in synchronism with the operations of the pre-form X-axis motor 811, the pre-form Y-axis motor 812 and the pre-form Y-axis motor 813.

As a result of this, with the die bonder according to the present invention, it is possible to achieve the die bonding having less unevenness or un-uniformity of the wetting, even for the application area and a die, in the form of an oblong having a longitudinal side quite longer than the short side thereof.

### Embodiment 3

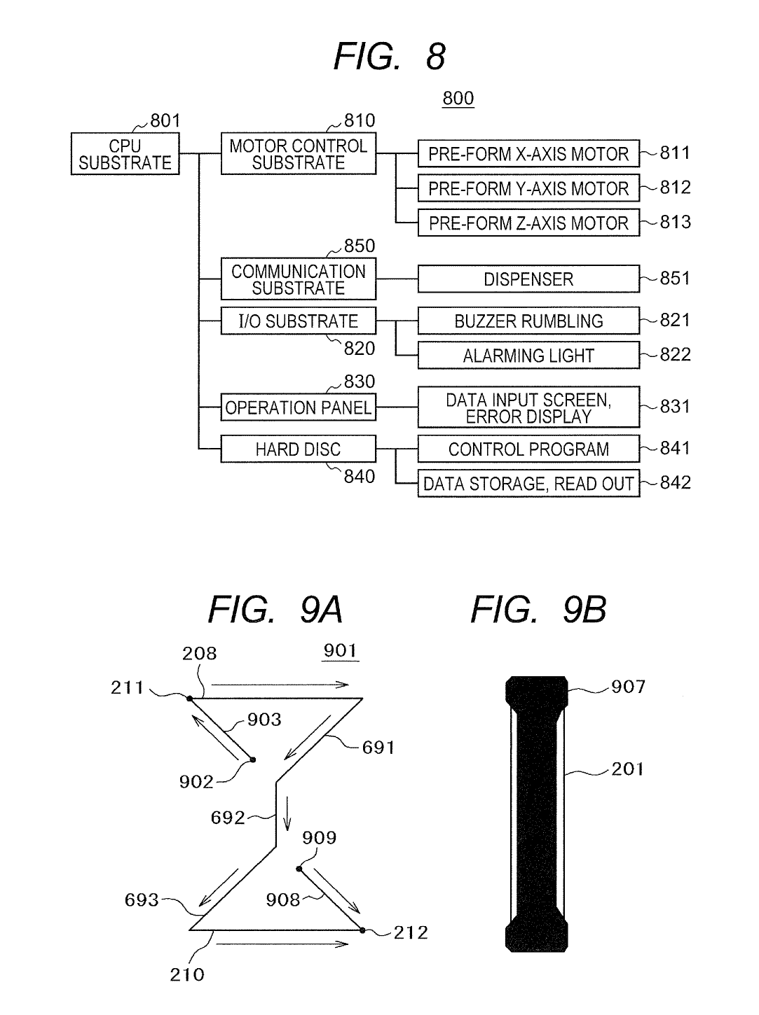

Explanation will be given on other embodiments of the drawing pattern to be applied in the present invention, by referring to FIGS. 9A and 9B. The FIGS. 9A and 9B show the other embodiments of the drawing pattern to be applied in the present invention. FIG. 9A is a view for showing the drawing routes of the drawing pattern. Also, FIG. 9B is a view for showing the paste drawn.

The drawing pattern shown in FIG. 9A is made up with a drawing route 903, provided for drawing obliquely from a lower direction on the right side, starting from a drawing start-point 902 and reaching to the drawing start-point 211 of the drawing pattern, which is explained by referring to FIGS. 6A to 6C, and also a drawing route 908, provided for drawing obliquely from an upper direction on the left side, starting from the drawing end-point 212, which is explained by referring to FIGS. 6A to 6C, and reaching to a drawing end-point 909. Of course, the paste is drawn/applied from the drawing start-point 211 to the drawing end-point 909, continuously. As a result of this, the paste 907 is formed on the application area 201, as is shown in FIG. 9B.

With the drawing pattern, according to the embodiments shown in FIGS. 9A and 9B, it is possible to further lessen the areas of the margin potions 615 and 616 shown in FIGS. 6A to 6C, and to reduce the unevenness or un-uniformity of the wetting.

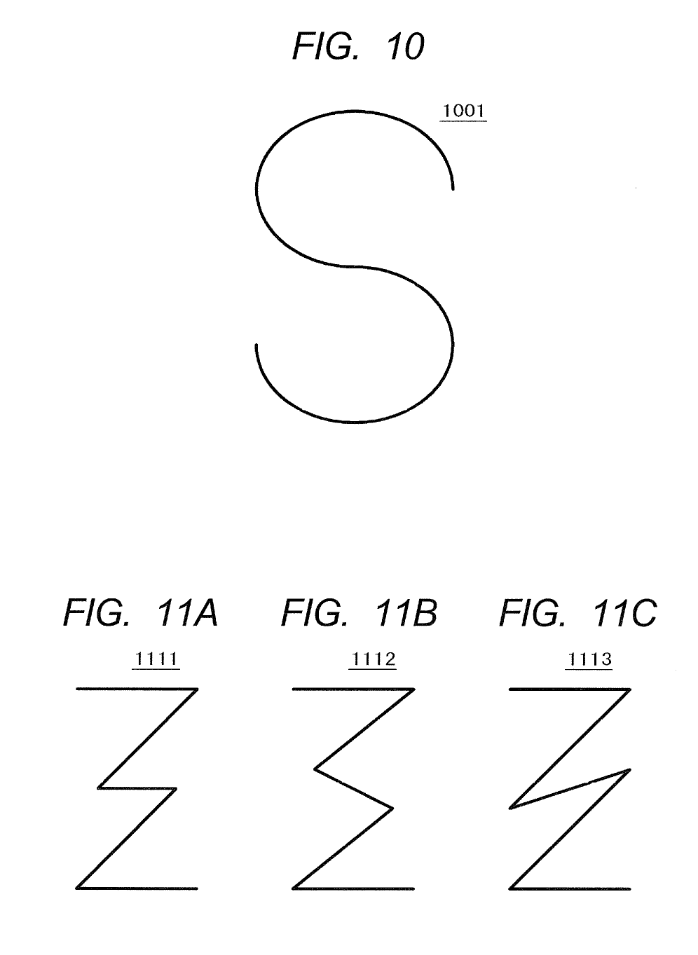

Also, FIG. 10 shows other example of the drawing pattern to be applied in the present invention. This FIG. 10 shows a drawing pattern obtained by curving the drawing pattern of the embodiment shown in FIGS. 9A and 9B. As is show by the S-like shaped drawing pattern 1001 shown in FIG. 10, a part or an entire of the drawing pattern may be curved. However, in this manner, it is a matter of course, that the pattern may be drawn, reversely, left and right thereof.

FIGS. 11A to 11C also show other embodiments of the drawing pattern to be applied in the present invention. Thus, the drawing patterns 1111, 1112 and 1113 shown in FIGS. 11A to 11C are achieved by drawing/applying the paste, obliquely, but not in the manner of the straight line from the upper to the lower along the drawing route 692 of the embodiment shown in FIGS. 6A to 6C, and thereby reducing the unevenness or un-uniformity of the wetting, and also reducing the margin portions.

As a result of this, it is possible to make the margin portions small. As a result of this, it is possible to reduce the unevenness or un-uniformity of the wetting, if boding the die thereon.

The present invention is also applicable to a manufacturing apparatus for applying filler, such as, for use of chip coating, etc., on a semiconductor element, for example, LED, LSI, etc., other than for applying a liquid-like adhesive for use of die bonding or a liquid-like adhesive for use of mounting, on the substrate to be applied, such as, a printed board, etc.

The present invention may be embodied in other specific forms without departing from the spirit or essential feature or characteristics thereof. The present embodiment(s) is/are therefore to be considered in all respects as illustrative and not restrictive, the scope of the invention being indicated by the appended claims rather than by the forgoing description and range of equivalency of the claims are therefore to be embraces therein.

What is claimed is:

1. A paste applying apparatus, for applying a paste within an application area, with discharging the paste from a nozzle, comprising:
a discharge portion, which is configured to discharge the paste from the nozzle of a syringe;
a moving portion, which is configured to move said nozzle in relative to a predetermined application area of a substrate; and
a controller portion, wherein
a drawing pattern is determined in advance, within said application area, for each of said application areas, and said drawing pattern has, at least, a first drawing route and a fifth drawing route for drawing in horizontal direction, a second drawing route and a fourth drawing route for drawing obliquely, and further a third drawing route, in vicinity of a side of said application area in the horizontal direction, and
said controller portion controls said discharge portion and said moving portion, so that said paste is applied, continuously, from a drawing start-point to a drawing end-point, which are determined in advance, through said first drawing route, said second drawing route, said third drawing route, said fourth drawing route and said fifth drawing route.

2. The paste applying apparatus, as described in the claim 1, wherein said application area is an oblong, having a long side in vertical direction with respect to other side in said horizontal direction.

3. The paste applying apparatus, as described in the claim 1, wherein said third drawing route lies in a direction perpendicular to the side of the application area in said horizontal direction.

4. The paste applying apparatus, as described in the claim 2, wherein said third drawing route lies in a direction perpendicular to the side of the application area in said horizontal direction.

5. A paste applying method for an apparatus, applying a paste within an application area, with discharging the paste from a nozzle, comprising:
a discharge portion, which is configured to discharge the paste from the nozzle of a syringe;
a moving portion, which is configured to move said nozzle in relative to a predetermined application area of a substrate; and
a controller portion, in said method;
a drawing pattern is determined in advance, within said application area, for each of said application areas, and said drawing pattern has, at least, a first drawing route and a fifth drawing route for drawing in horizontal direction, a second drawing route and a fourth drawing route for drawing obliquely, and further a third drawing route, in vicinity of a side of said application area in the horizontal direction; and
said controller portion controls said discharge portion and said moving portion, so that said paste is applied, continuously, from a drawing start-point to a drawing end-point, which are determined in advance, through said first drawing route, said second drawing route, said third drawing route, said fourth drawing route and said fifth drawing route.

6. The paste applying method, as described in the claim 5, wherein said application area is an oblong, having a long side in vertical direction with respect to other side in said horizontal direction.

7. The paste applying method, as described in the claim 5, wherein said third drawing route lies in a direction perpendicular to the side of the application area in said horizontal direction.

8. The paste applying method, as described in the claim 6, wherein said third drawing route lies in a direction perpendicular to the side of the application area in said horizontal direction.

9. A die bonder comprising:
a wafer supply portion, which is configured to supply a die;
a work supply/transfer portion, which is configured to transfer a substrate;
a pre-form portion, having a syringe for applying a paste within an application area by discharging an adhesive onto said substrate and a driving mechanism, which is configured to move said syringe;
a bonding head portion, which is configured to bond said die on said application area of said substrate, on which said paste is applied; and
a controller portion, which is configured to control said wafer supply portion, said work supply/transfer portion, said pre-form portion and said bonding head portion, wherein
a drawing pattern is determined in advance, within said application area, for each of said application areas, and said drawing pattern has, at least, a first drawing route and a fifth drawing route for drawing in horizontal direction, a second drawing route and a fourth drawing route for drawing obliquely, and further a third drawing route, in vicinity of a side of said application area in the horizontal direction,
said pre-form portion comprises a discharge portion, which is configured to discharge the paste from said nozzle of said syringe, a moving portion, which is configured to move said nozzle in relative to a predetermined application area of a substrate, and a controller portion, wherein
said controller portion controls said discharge portion and said moving portion, so that said paste is applied, continuously, from a drawing start-point to a drawing end-point, which are determined in advance, through said first drawing route, said second drawing route, said third drawing route, said fourth drawing route and said fifth drawing route.
